(19) United States
(12) Patent Application Publication
(10) Pub. No.: US 2019/0198594 A1
(43) Pub. Date: Jun. 27, 2019

(54) DISPLAY APPARATUS AND METHOD OF MANUFACTURING THE SAME

(71) Applicant: Samsung Display Co., Ltd., Yongin-si (KR)

(72) Inventors: Pilsuk Lee, Yongin-si (KR); Jintaek Kim, Yongin-si (KR); Kiwan Ahn, Yongin-si (KR)

(21) Appl. No.: 16/228,846

(22) Filed: Dec. 21, 2018

(30) Foreign Application Priority Data
Dec. 21, 2017 (KR) 10-2017-0177487

(51) Int. Cl. H01L 27/32; H01L 51/00

(52) U.S. Cl. CPC H01L 27/3262; H01L 51/0097; H01L 21/02592; H01L 2251/5338; H01L 2227/323

(57) ABSTRACT

A method of manufacturing a display apparatus includes: crystallizing portions of an amorphous silicon layer to form a preliminary semiconductor layer defining a channel region of a thin film transistor (“TFT”), a preliminary source and drain region disposed at opposing sides of the channel region, respectively, and an amorphous silicon layer region of the TFT, disposed between the channel region and the preliminary source or drain region; forming a source and drain region of the TFT at the opposing sides of the channel region, respectively, by doping the preliminary source and drain regions; and forming a source and drain electrode of the TFT respectively connected to the source and drain regions, where the semiconductor layer includes the amorphous silicon layer region connecting the channel region to at least one of the source and drain regions, and forming a display device connected to the TFT including the amorphous silicon layer region.

This application claims priority to Korean Patent Application No. 10-2017-0177487, filed on Dec. 21, 2017, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the same.

### 2. Description of the Related Art

Generally, display apparatuses may be used for mobile apparatuses such as smartphones, laptop computers, digital cameras, camcorders, personal digital assistants (“PDAs”), notebook computers and tablet personal computers (“PCs”), or electronic apparatuses such as watches, desktop computers, televisions, outdoor billboards, display apparatuses for exhibition, dashboards for automobiles and head up displays (“HUDs”).

Display apparatuses having a reduced overall thickness are desired in the market.

Flexible display apparatuses are easy to carry and are applicable to mobile or electronic apparatuses of various shapes. Among them, display apparatuses based on organic light-emitting display technology are the most promising flexible display apparatuses.

Display apparatuses are classified into passive matrix display apparatuses and active matrix display apparatuses according to a driving method thereof. The active matrix display apparatuses include thin film transistors (“TFTs”) serving as switching transistors. In the TFTs, an off leakage is reduced to secure reliability thereof during an off state and improvement of drain current change (ΔIds) characteristics thereof is desired.

### SUMMARY

One or more embodiments include a display apparatus for securing reliability of an electronic device, reducing an off leakage therein, and improving drain (electrical) current change characteristics, and a method of manufacturing the display apparatus.

Additional features will be set forth in part in the description which follows and, in part, will be apparent from the description, or may be learned by practice of the presented embodiments.

According to one or more embodiments, a method of manufacturing a display apparatus includes: forming an amorphous silicon layer on a substrate; forming a thin film transistor of the display apparatus on the substrate, including: selectively crystallizing portions of the amorphous silicon layer on the substrate, by irradiating the portions of the amorphous silicon layer with a laser beam, to form a preliminary semiconductor layer defining a channel region of a semiconductor layer of the thin film transistor, a preliminary source region and a preliminary drain region which are disposed at opposing sides of the channel region, respectively, and an amorphous silicon layer region of the semiconductor layer of the thin film transistor, disposed between the channel region and at least one of the preliminary source region and the preliminary drain region; forming a source region and a drain region of the semiconductor layer of the thin film transistor at opposing sides of the channel region, respectively, by doping the preliminary source region and the preliminary drain region of the preliminary semiconductor layer with impurity ions; and forming a source electrode and a drain electrode of the thin film transistor respectively connected to the source region and the drain region of the semiconductor layer of the thin film transistor, where the semiconductor layer of the thin film transistor includes each of the channel region, the source region, the drain region and the amorphous silicon layer region connecting the channel region to at least one of the source region and the drain region, and forming on the substrate, a display device of the display apparatus which emits light to display an image, the display device connected to the thin film transistor including each of the channel region, the source region, the drain region and the amorphous silicon layer region connecting the channel region to the least one of the source region and the drain region.

Within the thin film transistor of the display apparatus: the source region or the drain region may contact the source electrode or the drain electrode, respectively, to be electrically connected thereto, contact of the source region or the drain region with the source electrode or the drain electrode, respectively, may define a contact region of the thin film transistor, and within the semiconductor layer of the thin film transistor, the amorphous silicon layer region may be between the channel region and the contact region.

The selectively crystallizing of the portions of the amorphous silicon layer may include: providing a mask including a plurality of openings above the substrate; and applying the laser beam from above the mask towards the substrate to: crystallize first regions of the amorphous silicon layer respectively corresponding to the channel region, the source region and the drain region of the semiconductor layer of the thin film transistor, and not crystallize a second region of the amorphous silicon layer corresponding to the amorphous silicon layer region of the semiconductor layer of the thin film transistor.

The applying of the laser beam from above the mask and towards the amorphous silicon layer on the substrate may include: applying the laser beam to the first regions of the amorphous silicon layer, via the openings in the mask, to crystallize the first regions of the amorphous silicon layer, the crystallized first regions defining the preliminary source region and the preliminary drain region of the preliminary semiconductor layer, and not applying the laser beam to the second region of the amorphous silicon layer, to not crystallize the second region of the amorphous silicon layer, the non-crystallized second region defining the amorphous silicon layer region of the semiconductor layer of the thin film transistor.

The mask may include an optical mask.

The forming of the source region and the drain region may include: forming a first insulating layer disposing the preliminary semiconductor layer between the first insulating layer and the substrate; forming a gate electrode disposing the first insulating layer between the gate electrode and the preliminary semiconductor layer; and forming the source region and the drain region by respectively implanting the impurity ions to the preliminary source region and the preliminary drain region of the preliminary semiconductor layer using the gate electrode as a mask.

The gate electrode may overlap an entirety of the channel region and the amorphous silicon layer region of the preliminary semiconductor layer.

The forming of the source electrode and the drain electrode may include: forming a second insulating layer disposing the gate electrode between the second insulating layer and the first insulating layer; forming a contact hole in plurality respectively exposing the source region and the drain region, by etching portions of the first insulating layer and portions of the second insulating layer respectively corresponding to the source region and the drain region; and connecting the source electrode and the drain electrode to the source region and the drain region, at the contact holes, respectively.

The amorphous silicon layer region may be only between the channel region and the drain region.

The selectively crystallizing of the portions of the amorphous silicon layer may include crystallizing the portions of amorphous silicon layer into a polycrystalline silicon layer by excimer laser annealing.

The substrate may include a rigid substrate.

The substrate may include a flexible substrate.

The method may further include forming at least one of a barrier layer and a buffer layer between the substrate and the preliminary semiconductor layer.

The display device may include an organic light-emitting device.

According to one or more embodiments, a display apparatus includes: a substrate; a thin film transistor on the substrate, including: a semiconductor layer including: a channel region, a source region and a drain region; and an amorphous silicon layer region disposed between the channel region and at least one of the source region and the drain region, a gate electrode on the semiconductor layer; and a source electrode and a drain electrode respectively connected to the source region and the drain region; a display device which emits light to display an image, connected to the thin film transistor including the amorphous silicon layer region disposed between the channel region and the least one of the source region and the drain region on the substrate; and a plurality of insulating layers respectively between the semiconductor layer and the gate electrode, between the gate electrode and each of the source and drain electrodes, and between the display device and each of the source and drain electrodes.

The source region or the drain region may contact the source electrode or the drain electrode, respectively, to be connected thereto, contact of the source region or the drain region with the source electrode or the drain electrode, respectively, may form a contact region of the thin film transistor, and the amorphous silicon layer region may be between the channel region and the contact region.

The gate electrode may overlap an entirety of the channel region and the amorphous silicon layer region.

The amorphous silicon layer region may be only between the channel region and the drain region.

The display apparatus may further include at least one of a barrier layer and a buffer layer between the substrate and the semiconductor layer.

The display device may include an organic light-emitting device.

### BRIEF DESCRIPTION OF THE DRAWINGS

These and/or other features will become apparent and more readily appreciated from the following description of the embodiments, taken in conjunction with the accompanying drawings in which:

FIG. 1 is a cross-sectional view illustrating an embodiment of a sub-pixel of a display apparatus, according to the invention;

FIG. 2A is a cross-sectional view illustrating an embodiment of forming an amorphous silicon layer on a substrate, in a method of manufacturing the display apparatus of FIG. 1;

FIG. 2B is a cross-sectional view illustrating an embodiment of crystallizing the amorphous silicon layer on the substrate of FIG. 2A, in a method of manufacturing the display apparatus of FIG. 1;

FIG. 2C is a cross-sectional view illustrating an embodiment of forming a semiconductor layer on the substrate of FIG. 2B, in a method of manufacturing the display apparatus of FIG. 1;

FIG. 2D is a cross-sectional view illustrating an embodiment of forming a first insulating layer and a gate electrode on the substrate of FIG. 2C, in a method of manufacturing the display apparatus of FIG. 1;

FIG. 2E is a cross-sectional view illustrating an embodiment of forming a source region and a drain region from a layer on the substrate of FIG. 2D, in a method of manufacturing the display apparatus of FIG. 1;

FIG. 2F is a cross-sectional view illustrating an embodiment of forming a second insulating layer on the substrate of FIG. 2E, in a method of manufacturing the display apparatus of FIG. 1;

FIG. 2G is a cross-sectional view illustrating an embodiment of forming a contact hole in a layer on the substrate of FIG. 2F in a method of manufacturing the display apparatus of FIG. 1;

FIG. 2H is a cross-sectional view illustrating an embodiment of forming a raw material for source and drain electrodes on the substrate of FIG. 2G in a method of manufacturing the display apparatus of FIG. 1;

FIG. 2I is a cross-sectional view illustrating an embodiment of forming a source electrode and a drain electrode from a layer on the substrate of FIG. 2H in a method of manufacturing the display apparatus of FIG. 1; and

FIG. 3 is a cross-sectional view illustrating an embodiment of a semiconductor layer of a display apparatus on a substrate thereof, according to the invention.

### DETAILED DESCRIPTION

As the disclosure allows for various changes and numerous embodiments, example embodiments will be illustrated in the drawings and described in detail in the written description. Effects and features of the disclosure and methods of accomplishing these will be apparent when embodiments described with reference to the drawings are referred to. This disclosure may, however, be embodied in many different forms and should not be construed as limited to the example embodiments set forth herein.

Sizes of elements in the drawings may be exaggerated for convenience of explanation. In other words, since sizes and thicknesses of components in the drawings are arbitrarily illustrated for convenience of explanation, the following embodiments are not limited thereto.

In the following examples, first, second and third directions such as represented by the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Hereinafter, embodiments of a display apparatus will be described more fully with reference to the accompanying drawings, in which example embodiments of the disclosure are shown. When description is given with reference to the drawings, like reference numerals in the drawings denote like or corresponding elements, and repeated description thereof will be omitted.

It will be understood that when an element is referred to as being related to another elements such as being “on” another element, it can be directly on the other element or intervening elements may be present therebetween. In contrast, when an element is referred to as being related to another elements such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Expressions such as “at least one of,” when preceding a list of elements, modify the entire list of elements and do not modify the individual elements of the list. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Generally, display apparatuses use a relatively lightly doped drain (“LDD”) structure to secure reliability of TFTs. However, when the TFTs having an LDD structure are used, driving current decreases and the number of mask processes increases within a method of manufacturing undesirably increases. Accordingly, process yield undesirably decreases and manufacturing costs undesirably increase.

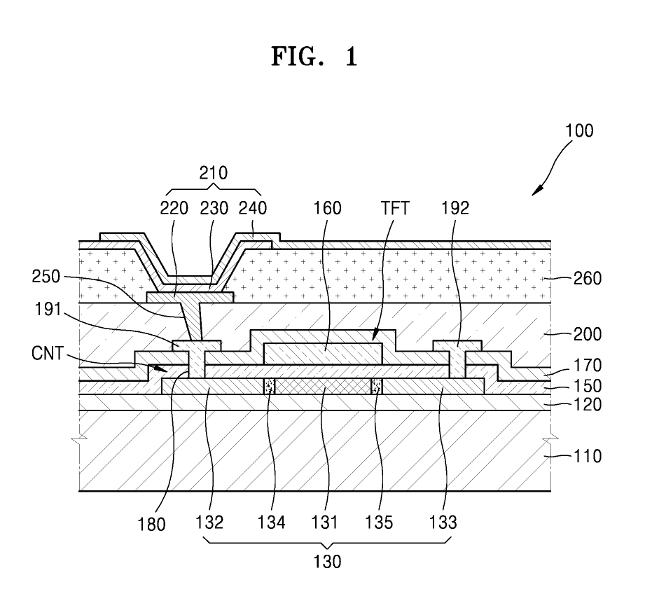

FIG. 1 is a cross-sectional view illustrating an embodiment of a sub-pixel of a display apparatus 100, according to the invention. At the sub-pixel of the display apparatus 100, light may be emitted to display an image. The sub-pixel may include a light-emission area at which light is emitted to display the image and a non-emission area at which light is not emitted. The display apparatus 100 may include a plurality of sub-pixels arranged therein in an overall display area at which the image is displayed. The display apparatus 100 may further include a non-display area at which the sub-pixels are not arranged and the image is not displayed.

In an embodiment, the display apparatus 100 may be an organic light-emitting display which displays an image with light generated and emitted therein (e.g., a self-emissive display), without being limited thereto. In embodiments, the display apparatus 100 may be a display which displays an image with light generated outside thereof and emitted thereto. In some embodiments, the display apparatus 100 may be, but is not limited to, a liquid crystal display (“LCD”), a field emission display (“FED) or an electronic paper display (“EPD”).

The display apparatus and components thereof are may be disposed in a plane defined by first and second directions which cross each other. A thickness of the display apparatus and components thereof may be taken in a third direction crossing each of the first and second directions.

Referring to FIG. 1, the display apparatus 100 includes a substrate 110 on which layers of the display apparatus 100 are disposed and/or formed. The substrate 110 may be a relatively rigid substrate or a relatively flexible substrate. The substrate 110 may be common to each of a plurality of sub-pixels of the display apparatus 100. One or more layers disposed on the substrate 110 may also be common to more than one sub-pixel of the display apparatus 100. Various structures on the substrate 110 may define the sub-pixel of the display apparatus 100.

An insulating layer 120 may be on the substrate 110. The insulating layer 120 includes at least one of a barrier layer and a buffer layer.

A semiconductor layer 130 is on the insulating layer 120. The semiconductor layer 130 includes or defines a channel region 131, and a source region 132 and a drain region 133 respectively at opposing sides of the channel region 131.

The channel region 131 may not be doped with impurities, or may be doped with less impurities than that of the source and/or drain regions 132 and 133. The source region 132 and the drain region 133 may be doped with N-type impurity ions or P-type impurity ions. A source electrode 191 may be electrically connected to the source region 132, and a drain electrode 192 may be electrically connected to the drain region 133.

Regarding the semiconductor layer 130, in a method of manufacturing a display apparatus, an amorphous silicon material layer may be deposited on the substrate 110, and may be selectively crystallized such as by using a laser beam. Excimer laser annealing (“ELA”) may be used to crystallize the amorphous silicon material layer. The amorphous silicon material layer as a relatively solid form may be melted or changed to a pliable or flowable form by an applied laser beam, and may be solidified again and crystallized to form a portion of the display apparatus.

Some regions of the semiconductor layer 130 may include a portion of the amorphous silicon material layer which is not irradiated with a laser beam to maintain amorphous silicon layer regions 134 and 135. That is, the amorphous silicon layer regions 134 and 135 may be non-crystallized regions of the amorphous silicon material layer. The amorphous silicon layer regions 134 and 135 may also be non-doped regions of the amorphous silicon material layer as well as being non-crystallized, without limitation. Among portions of the finished semiconductor layer 130, the amorphous silicon layer regions 134 and 135 may be at least one of a region between the channel region 131 and the source region 132 and a region between the channel region 131 and the drain region 133.

In detail, the source region 132 or the drain region 133 are electrically connected to the source electrode 191 or the drain electrode 192, respectively, to form a contact region CNT. The contact region CNT may be at an outer side of the semiconductor layer 130, such as disposed at an end portion of the semiconductor layer 130. The amorphous silicon layer regions 134 and 135 may be at an inner side of the contact region CNT, such as closer to a center portion of the semiconductor layer 130 or the channel region 131 thereof. In some embodiments, the amorphous silicon layer region 135 may be only between the channel region 131 and the drain region 133 and the amorphous silicon layer region 134 may be omitted.

The amorphous silicon layer regions 134 and 135 may have relatively lower carrier mobility than that of the source region 132 and the drain region 133 respectively connected to the source electrode 191 and the drain electrode 192. Since the amorphous silicon layer regions 134 and 135 serve as a break between the channel region 131 and the source region 132 or between the channel region 131 and the drain region 133, a speed of hot carriers accelerated by a high electric field decreases. The hot carriers having slowed down fail to hurdle over a barrier of a first insulating layer 150 which is on the semiconductor layer 130. Accordingly, an off leakage of a thin film transistor TFT may increase, and drain (electrical) current change characteristics may improve.

The first insulating layer 150 may be on the semiconductor layer 130. The first insulating layer 150 may cover the semiconductor layer 130. The first insulating layer 150 may be a gate insulating layer. The first insulating layer 150 may be a single layer structure or a multiple layer structure.

A gate electrode 160 may be on the first insulating layer 150. The gate electrode 160 may include a single metal layer or a plurality of metal layers. In addition, the gate electrode 160 may be a single layer structure or a multiple layer structure. The gate electrode 160 may cover the channel region 131 and each of the amorphous silicon layer regions 134 and 135 at the opposing sides of the channel region 131. A dimension of the gate electrode 160 along a direction parallel to the substrate 110 may be equal to or larger than a total dimension of the channel region 131 and each of the amorphous silicon layer regions 134 and 135, so as to cover such regions. The direction parallel to the substrate 110 (e.g., horizontal in FIG. 1) may represent the first and/or second direction detailed above. A thickness of the display apparatus 100 and components thereof is taken in the vertical direction of FIG. 1.

A second insulating layer 170 may be on the gate electrode 160. The second insulating layer 170 may cover the gate electrode 160. The second insulating layer 170 may be an interlayer insulating layer. The second insulating layer 170 may be an organic material layer and/or an inorganic material layer.

The source electrode 191 and the drain electrode 192 may be on the second insulating layer 170. A portion of the first insulating layer 150 and a portion of the second insulating layer 170 may be selectively omitted or removed to form a contact hole 180. Through and at the contact hole 180, the source electrode 191 may be electrically connected to the source region 132 and the drain electrode 192 may be electrically connected to the drain region 133.

A third insulating layer 200 may be on the source electrode 191 and the drain electrode 192. The third insulating layer 200 may cover the source electrode 191 and the drain electrode 192. The third insulating layer 200 may be a passivation layer or a planarization layer.

The thin film transistor TFT may be electrically connected to a display device 210 at which light is emitted to display an image. A light emission area may include the display device 210 while a remainder of the sub-pixel is a non-emission area at which light is not emitted and the image is not displayed. In an embodiment, the display device 210 may be, for example, an organic light-emitting device. However, the present disclosure is not limited thereto, and various display devices are applicable.

The display device 210 may be on the third insulating layer 200. The display device 210 includes a first electrode 220, an intermediate layer 230 and a second electrode 240. The thin film transistor TFT electrically connected to the display device 210 may control the display device 210 to generate and/or emit light for displaying an image. That is, an image of the display apparatus 100 may be displayed under control of the thin film transistor TFT.

The first electrode 220 may be connected to one of the source electrode 191 and the drain electrode 192 through and at a contact hole 250. A pixel-defining layer 260 may be on the third insulating layer 200. The pixel-defining layer 260 defines a light emission region of each sub-pixel. A boundary of the light emission region may be defined by edges of the first electrode 220 which are surrounded by the pixel-defining layer 260.

On the first electrode 220, the intermediate layer 230 may be in a region exposed which is exposed from the pixel-defining layer 160. In an embodiment of manufacturing a display apparatus, the first electrode 220 may be exposed at the light emission region such as by etching a portion of a material layer for forming the pixel-defining layer 260. The intermediate layer 230 may be formed by a deposition process in the method of manufacturing the display apparatus.

The second electrode 240 may be on the intermediate layer 230.

In an embodiment, a plurality of sub-pixels of the display apparatus 100 may be formed over or defined on the substrate 110. In an embodiment, for example, red, green, blue or white color may be displayed with respect to each sub-pixel. However, the present disclosure is not limited thereto.

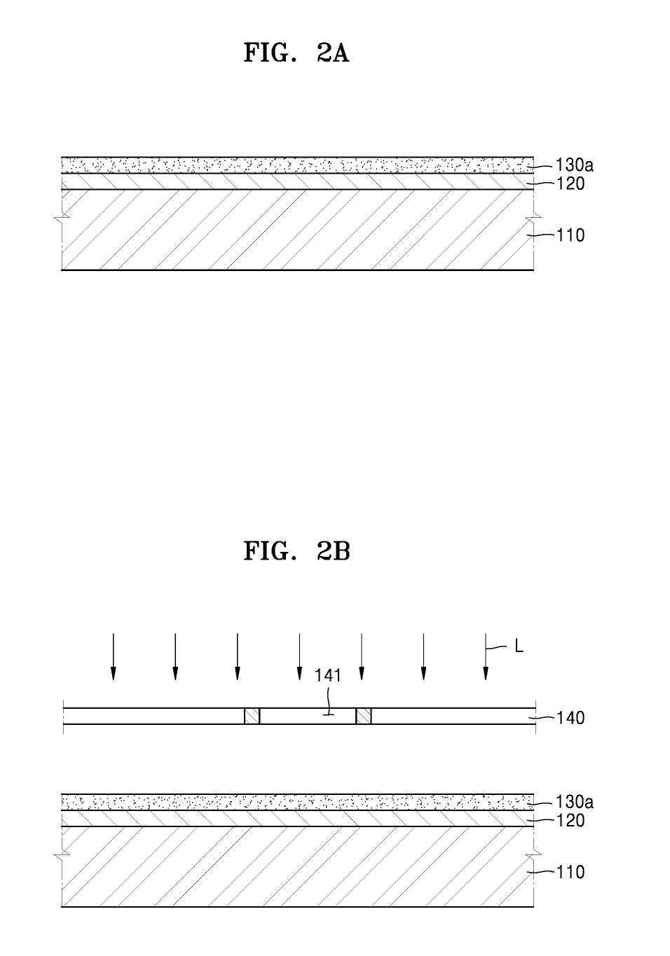

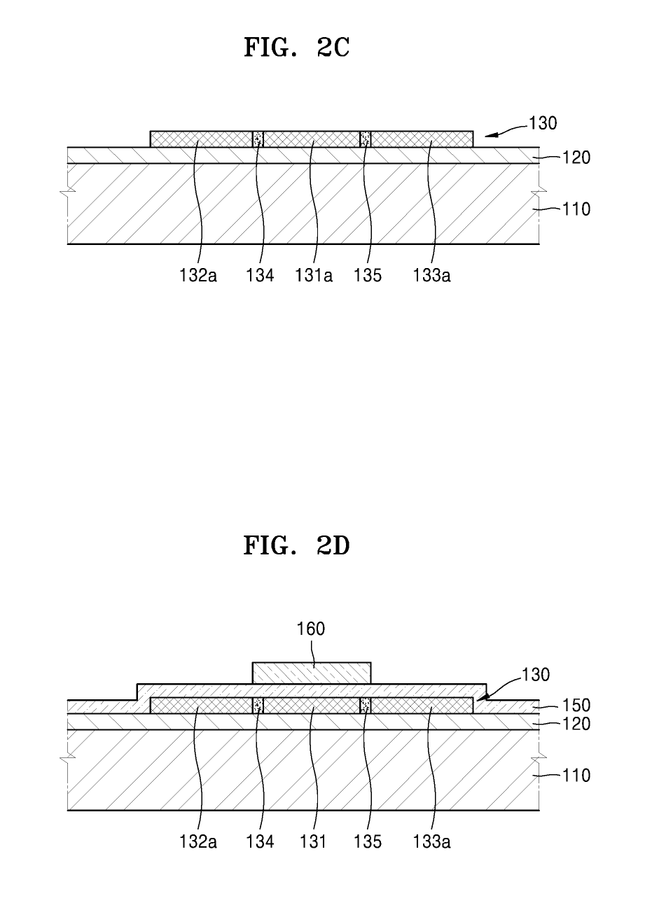

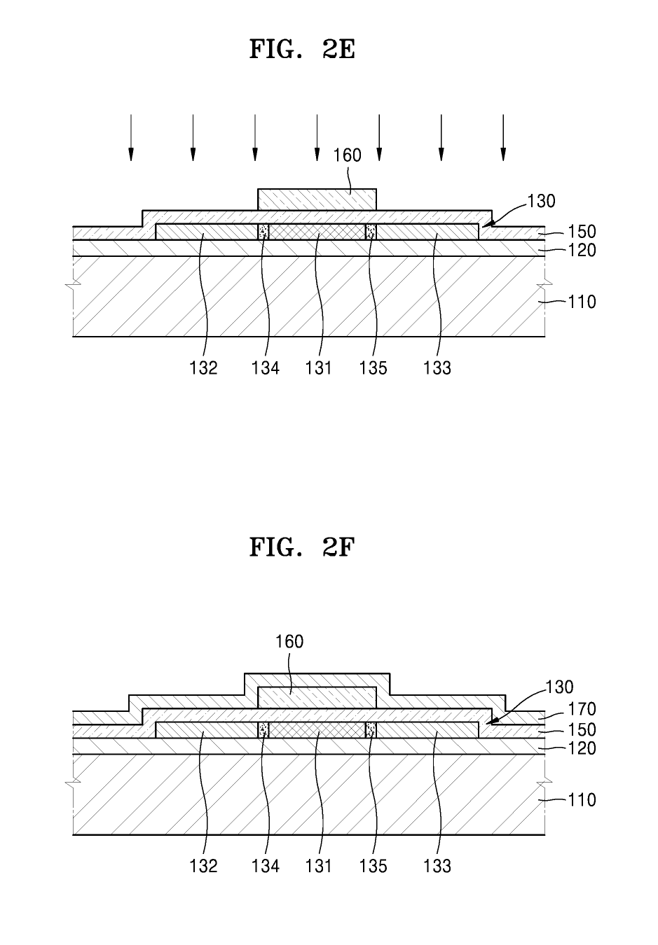

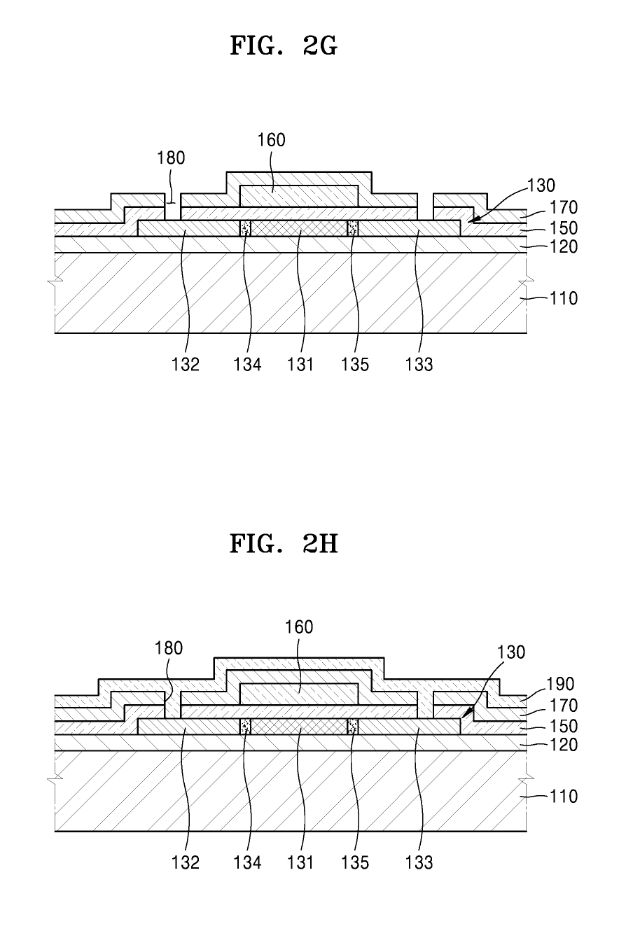

FIGS. 2A to 2I schematically illustrate embodiments of processes within a method of manufacturing the display apparatus 100 of FIG. 1.

Referring to FIG. 2A, the substrate 110 is provided. The substrate 110 may be a relatively rigid substrate. As an embodiment of a rigid substrate, for example, the substrate 110 may be a relatively rigid glass substrate or a relatively rigid polymer substrate. In some embodiments, the substrate 110 may be a flexible substrate. As an embodiment of a flexible substrate, for example, the substrate 110 may be a flexible glass substrate or a flexible polymer substrate.

The insulating layer 120 is formed on an upper surface of the substrate 110. The insulating layer 120 includes at least one of a barrier layer and a buffer layer. The insulating layer 120 may be an organic material layer, an insulating layer, or a layer in which an organic layer and an insulating layer are alternately stacked. In addition, the insulating layer 120 may include at least one of silicon oxide (SiO₂) and silicon nitride (SiN). The insulating layer 120 may reduce or effectively prevent damage to the substrate 110 and/or may facilitate crystallization of the semiconductor layer 130. A material layer for forming the insulating layer 120 may be formed on an entirety of the substrate 100 or at an area which is common to plural sub-pixels of the display apparatus 100.

An amorphous silicon layer material 130a (α-Si) is formed on the insulating layer 120. In detail, the amorphous silicon layer 130a having a thickness of about 300 angstroms (Å) to about 700 Å is deposited on the insulating layer 120. The amorphous silicon material layer 130a may be deposited using a physical enhanced chemical vapor deposition (“PECVD”) apparatus or a radio frequency (“RF”) sputter. The amorphous silicon layer material 130a may be formed on a entirety of the substrate 100 or at an area which is common to plural sub-pixels of the display apparatus 100.

Referring to FIG. 2B, a mask 140 is provided above the substrate 110 having the insulating layer 120 and the amorphous silicon layer material 130a thereon. The mask 140 includes or defines an opening 141 in plurality through which a laser beam L may pass to the layers on the substrate 110. The mask 140 may be an optical mask. The mask 140 is spaced above the substrate 110 and the layers thereon. In some embodiments, a pattern of the mask 140 which is disposed over the substrate 110 having the layers thereon may be formed by a photolithography process. The openings 141 of the mask 140 may correspond to various regions of the semiconductor layer 130 to be formed from the amorphous silicon layer 130a.

The laser beam L is applied from above the mask 140 towards the substrate 110 and the layers thereon. When the laser beam L is applied to the amorphous silicon layer material 130a, some regions of the amorphous material silicon layer 130a are crystallized and other regions of the amorphous silicon layer 130a are not crystallized.

In detail, when the laser beam L is applied to the amorphous silicon layer material 130a on the substrate 110, regions of the amorphous silicon material layer 130a onto which the laser beam L is applied through the plurality of openings 141 are crystallized into polycrystalline silicon layers 131a, 132a and 133a as shown in FIG. 2C. On the other hand, regions of the amorphous silicon material layer 130a onto which the laser beam L is not applied as failing to pass through the plurality of openings 141 are maintained as the amorphous silicon material layer regions 134 and 135. A preliminary semiconductor layer (130 in FIG. 2C) is formed to include the polycrystalline silicon layers 131a, 132a, and 133a and the amorphous silicon layer regions 134 and 135.

As described above, the amorphous silicon layer 130a is selectively crystallized by ELA to form the polycrystalline silicon layers 131a, 132a and 133a locally crystallized among portions of the amorphous silicon material layer 130a.

Referring still to FIG. 2C, the amorphous silicon material layer 130a formed in a region outside the semiconductor layer 130 in which patterns of the polycrystalline silicon layers 131a, 132a, and 133a and the amorphous silicon layer regions 134 and 135 is removed such as by a photolithography process. Portions of the insulating layer 120 are exposed from the semiconductor layer 130 by removal of the regions of the amorphous silicon material layer 130a outside the semiconductor layer 130.

The channel region 131 is formed from a portion of the preliminary semiconductor layer (130 in FIG. 2C).

Referring to FIG. 2D, the first insulating layer 150 is formed above the substrate 110 and the layers thereon. The first insulating layer 150 is deposited over the entire surface of the substrate 110 and the layers thereon to cover the preliminary semiconductor layer (130 in FIG. 2C). The first insulating layer 150 may be a gate insulating layer. The first insulating layer 150 may be a single layer structure including silicon oxide (SiO₂) or a double layer structure including silicon oxide (SiO₂) and silicon nitride (SiNₓ). A thickness of the first insulating layer 150 may be about 800 Å to about 1200 Å.

The gate electrode 160 is formed on the first insulating layer 150. The gate electrode 160 may include a single metal layer or a plurality of metal layers. The gate electrode 160 may be a single layer structure including molybdenum (Mo), molybdenum-tungsten (MoW), chromium (Cr), aluminum (Al), an Al alloy, magnesium (Mg), copper (Cu), titanium (Ti), silver (Ag), nickel (Ni), tungsten (W), gold (Au), etc., or a multiple layer structure including a combination thereof. As a structure of the gate electrode 160, for example, the gate electrode 160 may be a multiple layer structure including Mo/Al/Mo. In some embodiments, the gate electrode 160 may include a transparent conductive (material) film such as an indium tin oxide (“ITO”) film or an indium zinc oxide (“IZO”) film. Thus, the channel region 131 of the thin film transistor TFT at the gate electrode 160 may be formed from the polycrystalline silicon layer 131a.

Referring to FIG. 2E, the source region 132 and the drain region 133 are formed in the semiconductor layer 130 by an ion implantation process. In detail, with the gate electrode 160 as a mask, N-type impurity ions or P-type impurity ions are implanted to the polycrystalline silicon layers 132a and 133a not covered by the gate electrode 160 (refer to FIG. 2D) to form the source region 132 and the drain region 133 of the semiconductor layer 130. In this regard, the gate electrode 160 serving as a mask covers all of the channel region 131 and the amorphous silicon layer regions 134 and 135 which are respectively at opposing sides of the channel region 131. That is, the channel region 131 and the non-crystallized amorphous silicon layer regions 134 and 135 are not subject to the ion implantation process. Accordingly, the source region 132 and the drain region 133 each forming a contact region CNT are respectively located outside of the amorphous silicon layer regions 134 and 135 (refer to FIG. 1).

As described above, in the finally-formed semiconductor layer 130, the source region 132 and the drain region 133 are formed outside outer edges of the channel region 131, and the amorphous silicon layer regions 134 and 135 are formed between the channel region 131 and the source region 132 and between the channel region 131 and the drain region 133, respectively.

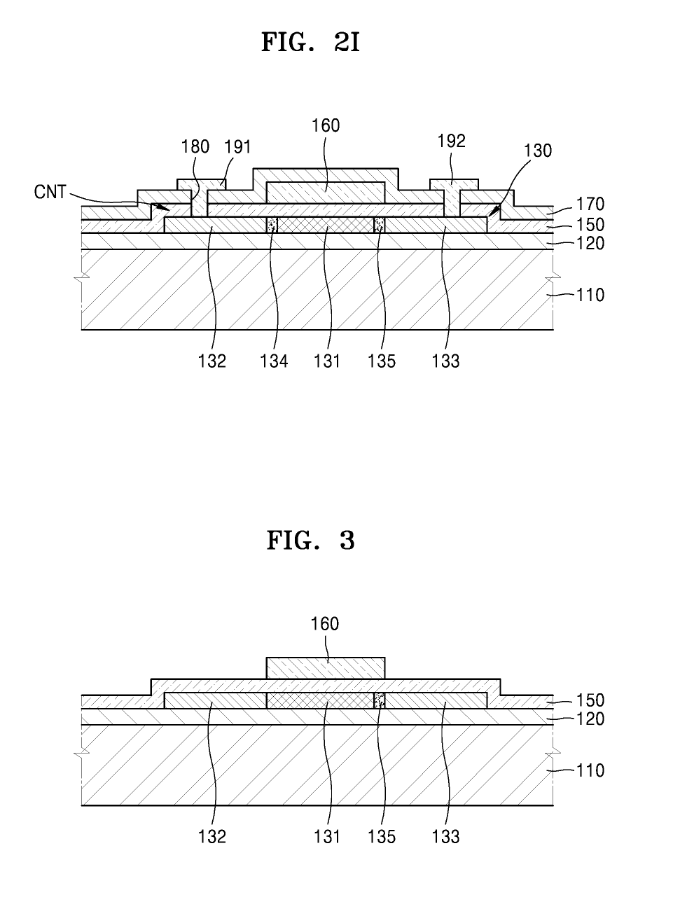

In some embodiments, as shown in FIG. 3, during an ELA process, the amorphous silicon layer region 135 may be formed only at one side of the channel region 131, such as at the drain region 133 to which a relatively stronger electric field is applied. In detail, the amorphous silicon layer region 135 may be located only between the channel region 131 and the drain region 133, as an alternative embodiment to the structure of FIG. 2E.

Referring to FIG. 2F, the second insulating layer 170 is formed on the gate electrode 160 along with other layers on the substrate 110. The second insulating layer 170 is deposited over the entire surface of the substrate 110 to cover the gate electrode 160 and the other layers on the substrate 110. The second insulating layer 170 may be an interlayer insulating layer. The second insulating layer 170 is a single layer structure including silicon oxide (SiO₂) or a double layer structure including silicon oxide (SiO₂) and silicon nitride (SiNₓ). A thickness of the second insulating layer 170 may be about 4000 Å to about 7000 Å.

Referring to FIG. 2G, a portion of each of the first insulating layer 150 and the second insulating layer 170 at the source region 132 and the drain region 133 are selectively removed such as by etching the portion of the first insulating layer 150 and a portion of the second insulating layer 170, and thus, the contact hole 180 is formed at each of the source region 132 and the drain region 133. By forming the contact hole 180 at each of the source region 132 and the drain region 133, surfaces of the source region 132 and the drain region 133 are partially exposed to outside the first insulating layer 150 and the second insulating layer 170.

Referring to FIG. 2H, a raw material 190 for forming source and drain electrodes is deposited over the entire surface of the substrate 110 and the layers thereon. The raw material 190 for forming the source and drain electrodes is deposited as a multilayer structure of Mo/Al/Mo. The raw material 190 for forming the source and drain electrodes fills the contact hole 180 at each of the source region 132 and the drain region 133. The raw material 190 for forming the source and drain electrodes covers both of the gate electrode 160 and the second insulating layer 170. A photoresist (not shown) is applied onto the raw material 190, and portions of the raw material 190 are etched to form the source and drain electrodes.

Referring to FIG. 2I, the source electrode 191 electrically connected to the source region 132 through and at the contact hole 180 and the drain electrode 192 electrically connected to the drain region 133 through and at the contact hole 180 are formed by etching the raw material 190 at positions where the source and drain electrodes 191 and 192 are to be formed (refer also to FIG. 1).

The source region 132 and the drain region 133 electrically connected to the source electrode 191 and the drain electrode 192 to form the contact region CNT at each of the source region 132 and the drain region 133 are located at opposing outer side portions of the semiconductor layer 130, and the amorphous silicon layer regions 134 and 135 are located at an inner side of the semiconductor layer 130 relative to the contact region CNT, respectively.

Referring again to FIG. 1, the third insulating layer 200 is formed on the substrate 110 and layers thereon. The third insulating layer 200 may cover the source electrode 191 and the drain electrode 192 and other layers illustrated in FIG. 2I. The third insulating layer 200 may be a passivation layer or a planarization layer. The third insulating layer 200 may include an organic material such as acryl, benzocyclobutene (“BCB”), or polyimide (“PI”), or an inorganic material such as SiNₓ. The third insulating layer 200 protects the thin film transistor TFT and the components thereof from elements outside thereof.

The display device 210 is formed on the substrate 110 including the various other layers thereon. In an embodiment, the display device 210 may be an organic light-emitting device but is not limited thereto, and various display devices are applicable.

The first electrode 220 of the display device 210 serving as an anode may be connected to one of the source electrode 191 and the drain electrode 192 through and at the contact hole 250 such as by etching the third insulating layer 200 to expose the one of the source electrode 191 and the drain electrode 192.

The first electrode 220, which serves as one of the electrodes included in the organic light-emitting device as the display device 210, may include various conductive materials. The first electrode 220 may be a transparent electrode or a reflective electrode. When the first electrode 220 is a transparent electrode, the first electrode 220 includes a transparent conductive material film. When the first electrode 220 is a reflective electrode, the first electrode 220 includes a reflective material film and a transparent conductive film which is on the reflective film. In an embodiment, the first electrode 220 may have a stacked structure including ITO/Ag/ITO.

A material layer for forming the pixel-defining layer 260 is patterned to expose at least a portion of the first electrode 220 at a light emission region of the display apparatus.

The intermediate layer 230 including an emission layer is formed over the exposed portion of the first electrode 220. The intermediate layer 230 may include an organic emission layer.

In some embodiments, the intermediate layer 230 may include an organic emission layer and may further include at least one of a hole injection layer (“HIL”), a hole transport layer (“HTL”), an electron transport layer (“ETL”) and an electron injection layer (“EIL”).

In an embodiment, the intermediate layer 230 may include an organic emission layer and may further include various functional layers.

The second electrode 240 serving as a cathode of the display device 210 is formed on the intermediate layer 230.

The second electrode 240 may be a transparent electrode or a reflective electrode.

When the second electrode 240 is a transparent electrode, the second electrode 240 includes a metal material film and a transparent conductive material film on the metal film. When the second electrode 240 is a reflective electrode, the second electrode 240 includes a metal material film.

Although not shown, a thin film encapsulation layer may cover the display device 210. Referring to the structure in FIG. 1, the thin film encapsulation layer may cover to the display device 210 and layers thereunder such that the display device 210 and portions of the underlying layers are not exposed outside the display apparatus (100 of FIG. 1). In the thin film encapsulation layer, an inorganic material film and an organic material film may be alternately stacked.

As described above, a display apparatus and a method of manufacturing the same, according to one or more embodiments, may reduce influence of hot carriers of a thin film transistor. Likewise, off leakage decreases and drain current change characteristics improve at the thin film transistor, and thus, reliability of the thin film transistor may be secured.

It should be understood that embodiments described herein should be considered in a descriptive sense only and not for purposes of limitation. Descriptions of features within each embodiment should typically be considered as available for other similar features in other embodiments.

While one or more embodiments have been described with reference to the figures, it will be understood by those of ordinary skill in the art that various changes in form and details may be made therein without departing from the spirit and scope as defined by the following claims.

What is claimed is:

1. A method of manufacturing a display apparatus, the method comprising:
forming an amorphous silicon layer on a substrate of the display apparatus;
forming a thin film transistor of the display apparatus on the substrate, comprising:
selectively crystallizing portions of the amorphous silicon layer on the substrate, by irradiating the portions of the amorphous silicon layer with a laser beam, to form a preliminary semiconductor layer defining:
a channel region of a semiconductor layer of the thin film transistor,
a preliminary source region and a preliminary drain region which are disposed at opposing sides of the channel region, respectively, and
an amorphous silicon layer region of the semiconductor layer of the thin film transistor, disposed between the channel region and at least one of the preliminary source region and the preliminary drain region;
forming a source region and a drain region of the semiconductor layer of the thin film transistor at the opposing sides of the channel region, respectively, by doping the preliminary source region and the preliminary drain region of the preliminary semiconductor layer with impurity ions; and
forming a source electrode and a drain electrode of the thin film transistor respectively connected to the source region and the drain region of the semiconductor layer of the thin film transistor,
wherein the semiconductor layer of the thin film transistor includes each of the channel region, the source region, the drain region and the amorphous silicon layer region connecting the channel region to at least one of the source region and the drain region, and
forming on the substrate, a display device of the display apparatus which emits light to display an image, the display device connected to the thin film transistor including each of the channel region, the source region, the drain region and the amorphous silicon layer region connecting the channel region to the least one of the source region and the drain region.

2. The method of claim 1, wherein within the thin film transistor of the display apparatus:
the source region or the drain region contacts the source electrode or the drain electrode, respectively, to be electrically connected thereto,
contact of the source region or the drain region with the source electrode or the drain electrode, respectively, defines a contact region of the thin film transistor, and
within the semiconductor layer of the thin film transistor, the amorphous silicon layer region is between the channel region and the contact region.

3. The method of claim 1, wherein the selectively crystallizing of the portions of the amorphous silicon layer comprises:
providing a mask comprising a plurality of openings, above the substrate; and
applying the laser beam from above the mask and towards the amorphous silicon layer on the substrate, to:
crystallize first regions of the amorphous silicon layer respectively corresponding to the channel region, the source region and the drain region of the semiconductor layer of the thin film transistor, and
not crystallize a second region of the amorphous silicon layer corresponding to the amorphous silicon layer region of the semiconductor layer of the thin film transistor.

4. The method of claim 3, wherein the applying of the laser beam from above the mask and towards the amorphous silicon layer on the substrate comprises:
applying the laser beam to the first regions of the amorphous silicon layer, via the openings in the mask, to crystallize the first regions of the amorphous silicon layer, the crystallized first regions defining the preliminary source region and the preliminary drain region of the preliminary semiconductor layer, and
not applying the laser beam to the second region of the amorphous silicon layer, to not crystallize the second region of the amorphous silicon layer, the non-crystallized second region defining the amorphous silicon layer region of the semiconductor layer of the thin film transistor.

5. The method of claim 3, wherein the mask comprises an optical mask.

6. The method of claim 3, wherein the forming of the source region and the drain region of the semiconductor layer of the thin film transistor comprises:
forming a first insulating layer disposing the preliminary semiconductor layer between the first insulating layer and the substrate;
forming a gate electrode disposing the first insulating layer between the gate electrode and the preliminary semiconductor layer; and
forming the source region and the drain region by respectively implanting the impurity ions to the preliminary source region and the preliminary drain region of the preliminary semiconductor layer, using the gate electrode as a mask.

7. The method of claim 6, wherein the gate electrode overlaps an entirety of each of the channel region and the amorphous silicon layer region of the preliminary semiconductor layer.

8. The method of claim 6, wherein the forming of the source electrode and the drain electrode comprises:
forming a second insulating layer disposing the gate electrode between the second insulating layer and the first insulating layer;
forming a contact hole in plurality respectively exposing the source region and the drain region, by etching portions of the first insulating layer and portions of the second insulating layer respectively corresponding to the source region and the drain region; and
connecting the source electrode and the drain electrode to the source region and the drain region, at the contact holes, respectively.

9. The method of claim 2, wherein within the semiconductor layer of the thin film transistor, the amorphous silicon layer region is only between the channel region and the drain region.

10. The method of claim 1, wherein the selectively crystallizing of the portions of the amorphous silicon layer comprises crystallizing the portions of the amorphous silicon layer into a polycrystalline silicon layer by excimer laser annealing.

11. The method of claim 1, wherein the substrate on which is formed the semiconductor layer of the thin film transistor including each of the channel region, the source region, the drain region and the amorphous silicon layer region connecting the channel region to the at least one of the source region and the drain region, comprises a rigid substrate.

12. The method of claim 1, wherein the substrate on which is formed the semiconductor layer of the thin film transistor including each of the channel region, the source region, the drain region and the amorphous silicon layer region connecting the channel region to the at least one of the source region and the drain region, comprises a flexible substrate.

13. The method of claim 1, further comprising forming at least one of a barrier layer and a buffer layer between the substrate and the preliminary semiconductor layer.

14. The method of claim 1, wherein the display device comprises an organic light-emitting device.

15. A display apparatus comprising:
a substrate;
a thin film transistor on the substrate, comprising;
a semiconductor layer comprising:
a channel region, a source region and a drain region; and
a non-doped amorphous silicon layer region disposed between the channel region and at least one of the source region and the drain region;
a gate electrode on the semiconductor layer; and
a source electrode and a drain electrode respectively connected to the source region and the drain region;
a display device which emits light to display an image, connected to the thin film transistor including the non-doped amorphous silicon layer region disposed between the channel region and the least one of the source region and the drain region, on the substrate; and
a plurality of insulating layers respectively between the semiconductor layer and the gate electrode, between the gate electrode and each of the source and drain electrodes, and between the display device and each of the source and drain electrodes.

16. The display apparatus of claim 15, wherein within the thin film transistor,
the source region or the drain region contacts the source electrode or the drain electrode, respectively, to be connected thereto;
contact of the source region or the drain region with the source electrode or the drain electrode, respectively, forms a contact region of the thin film transistor, and
within the semiconductor layer of the thin film transistor, the non-doped amorphous silicon layer region is between the channel region and the contact region.

17. The display apparatus of claim 15, wherein within the thin film transistor, the gate electrode overlaps an entirety of the channel region and the non-doped amorphous silicon layer region.

18. The display apparatus of claim 15, wherein within the semiconductor layer of the thin film transistor, the non-doped amorphous silicon layer region is only between the channel region and the drain region.

19. The display apparatus of claim 15, further comprising at least one of a barrier layer and a buffer layer between the substrate and the semiconductor layer.

20. The display apparatus of claim 15, wherein the display device comprises an organic light-emitting device.
